(19) United States
(12) Patent Application Publication
(10) Pub. No.: US 2021/0265749 A1
(43) Pub. Date: Aug. 26, 2021

(54) Device for Improving the Electromagnetic Compatibility of Electric/Electronic Devices, Device, and Assembly

(71) Applicant: Robert Bosch GmbH, Stuttgart (DE)

(72) Inventors: Thomas Goettel, Buch Am Wald (DE); Thomas Kimpel, Moessingen (DE); Ingmar Joas, Feuchtwangen (DE)

(21) Appl. No.: 17/259,420

(22) PCT Filed: May 11, 2019
(86) PCT No.: PCT/EP2019/062105

§ 371 Date: Jan. 11, 2021

(30) Foreign Application Priority Data
Jul. 12, 2018 (DE) 10 2018 211 622.9

(51) Int. Cl. H01R 4/48; B60T 7/04

(52) U.S. Cl. CPC H01R 4/4863; B60T 7/042

(57) ABSTRACT

A device for improving the electromagnetic compatibility of electric/electronic devices includes an electrically conductive spring element that is configured to be arranged between a first electric/electronic device and a second device in a biased manner in order to produce an electric connection between the two devices. The spring element has at least one helical spring with at least two winding sections running in opposite directions. The first electric/electronic device in one embodiment is a controller, and the second device in one embodiment is a brake system or actuator.

The invention relates to a device for improving the electromagnetic compatibility of electrical/electronic units, said device having an electrically conductive spring element that can be arranged pre-stressed between a first electrical/electronic unit, in particular a control unit, and a second unit, in particular a brake system or actuator, in order to produce an electrical connection between the two units.

Furthermore, the invention relates to an electrical/electronic unit having a device of this type and an assembly having two units between which a device of this type is provided.

### PRIOR ART

In order to improve the electromagnetic compatibility, it is known to produce electrical connections between one unit and another unit so that electrical energy is discharged free of interference in particular to ground. For example, control units for brake system control procedures are attached in motor vehicles as add-on control units directly to a hydraulic block or to an engine housing. The control units can output electromagnetic radiation which occurs for example as a result of the control unit being operated in a pulsating manner. In order to reduce this radiation, it is known to use a device that electrically connects the control unit in an electrical manner to the electrically conductive housing of the other unit, in particular engine, transmission or the like and as a consequence transmit the electromagnetic radiation directly into the housing and as a consequence protect other components from the electromagnetic radiation. Control units that are operated with high frequency pulsation must fulfil specific requirements relating to the electromagnetic compatibility. It is fundamentally known to provide as a device a spring element, a so-called EMV spring, which is pre-stressed between one unit and the other unit so that even if vibrations occur it is ensured that the spring element is reliably connected in an electrical manner. A low electrical resistance is of advantage for the effectiveness of the electrical connection. Moreover, in the case of high frequency applications, an inductive apparent resistance is also of importance.

### DISCLOSURE OF THE INVENTION

The device in accordance with the invention and having the features of claim 1 has the advantage that electromagnetic pulses are advantageously discharged owing to a reduced reactance of the spring element. In addition, additional electronic components are not required, as a result of which the device can be realized in a cost-effective manner and can also be used as a retrofit solution. It is provided for this purpose in accordance with the invention that a helical spring having two winding sections that are wound in opposite directions can be used as a spring element. As a result of the winding sections being wound in opposite directions, it is realized that the induced currents flow in opposite directions, as a result of which the reactance is reduced overall. In particular in the case of high frequency applications, this leads to the advantage of an improved electromagnetic compatibility of the unit that is electrically connected to another unit by means of this device. As a result of the invention, the inductance that is provided by the spring element and acts between the units is consequently overcome and the discharge behaviour improved.

In accordance with a preferred embodiment of the invention, the winding sections are embodied in a coaxial manner with respect to one another in two helical springs. Consequently, two helical springs are provided that lie in a coaxial manner with respect to one another, with the result that one helical spring is guided within the other helical spring, wherein in particular the outer diameter of the inner helical spring is smaller than the inner diameter of the outer helical spring.

The above mentioned advantage is realized as a result of the winding sections being embodied in opposite directions. Moreover, the coaxial arrangement ensures the advantage of a compact embodiment.

It is preferred that the two helical springs are embodied as one piece with one another, as a result of which an advantageous electrical conductor is ensured between the helical springs and it is ensured that the spring element can be handled in a simple manner.

Alternatively, the two helical springs are preferably embodied separately and attached to one another in an electrically conductive manner. The separate embodiment simplifies the production of the two helical springs which leads to corresponding cost advantages. The above mentioned advantages are ensured by means of the electrical connection.

In particular, the two helical springs are connected to one another in particular in a material-bonded manner at least at one spring wire end. As a consequence, a reliable electrical connection is ensured. It is preferred that the helical springs are each connected to one another at both spring wire ends in particular in a material bonded manner.

In accordance with an alternative embodiment of the invention, the winding sections are embodied in an axial manner one behind the other in one helical spring. As a consequence, the helical spring has a longer length in the axial direction but provides the advantage of a reduced number of parts which is correspondingly simpler to handle during the assembly process.

The unit in accordance with the invention and having the features of claim 8 is characterised by the device in accordance with the invention. This results in the already mentioned advantages. In particular, the unit is a control unit of a motor vehicle, in particular the control unit of a brake system that can be attached or is attached preferably to a hydraulic block or an engine housing which forms the second unit.

The assembly in accordance with the invention and having the features of claim 9 is characterised by the device in accordance with the invention or the unit in accordance with the invention. This results in the already mentioned advantages. In this case, the spring element is held in a pre-stressed manner between the first unit and the second unit with the result that by means of the elastic deformability of the spring element it is possible during operation to compensate in a reliable manner manufacturing and assembly tolerances and the advantageous electromagnetic compatibility is continuously insured. In particular, the first unit is the unit in accordance with the invention or the above-mentioned control unit. The second unit is in particular an electric motor, a transmission, a hydraulic block or the like, in particular of a brake system.

Furthermore, it is preferably provided that the helical spring lies axially at one end on an electrical connection contact of the printed circuit board and at the other end on an electrically conductive contact element of the second unit. As a consequence, a simple and reliable electrical connection for discharging electromagnetic pulses is provided.

It is particularly preferred that the electrically conductive contact element of the second unit is a housing or a housing part or motor part of the second unit. This results in the already mentioned advantages.

Further advantages and preferred features and feature combinations are disclosed in particular in the previous descriptions and also in the claims. The invention is to be further explained below with the aid of the drawing.

In the drawing:

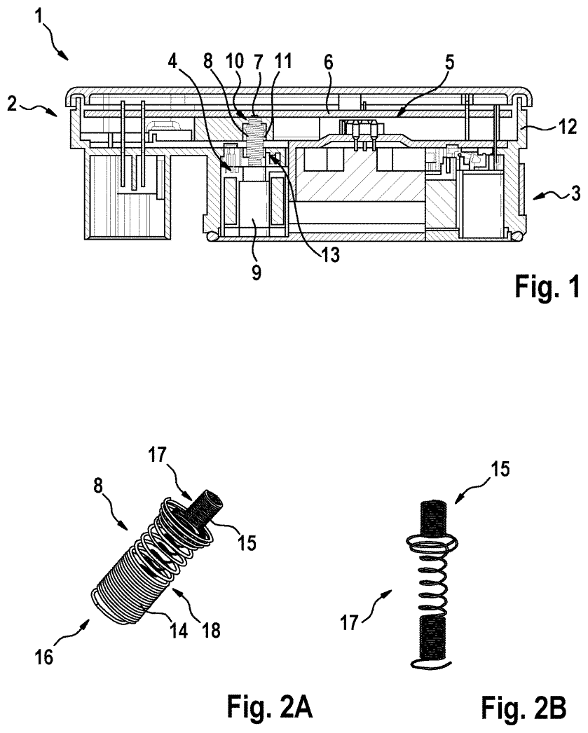

FIG. 1 illustrates a simplified sectional view of an advantageous assembly,

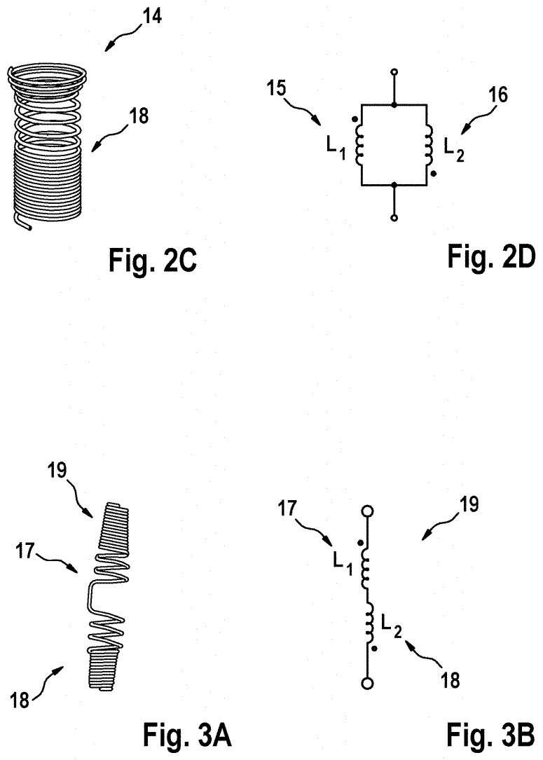

FIGS. 2A to 2D illustrate multiple views of an advantageous device of the assembly, and

FIGS. 3A and 3B illustrate different views of an alternative embodiment of the device.

FIG. 1 illustrates a simplified sectional view of an advantageous assembly 1 having a control unit 2 as a first unit and a brake system 3 as a second unit. The brake system 3 comprises an electromagnetic actuator 4 that can be controlled by means of the control unit 2 and in particular is used so as to actuate a valve (not illustrated). For this purpose, the control unit 2 comprises for example an electronic power system 5 that is arranged at least in parts on a printed circuit board 6. The printed circuit board comprises multiple electrically conductive tracks of which at least one terminates in an electrical connection contact 7, for example in the form of a contacting contact surface, or comprises such an electrical connection contact.

A spring element 8 is supported in an axial manner on the connection contact 7, said spring element lies at the other end against a housing 9 of the actuator 4. The spring element 8 is configured in an electrically conductive manner and consequently produces an electrical connection between the housing 9 and the printed circuit board 5. In this case the spring element 8 is embodied as a helical spring device 10 that is held guided at the side in a housing section 11 of a housing 12 of the control unit 2 and/or of the hydraulic system 3 with the result that the spring element 8 is reliably prevented from buckling even in the case of a high axial load.

The spring element 8 forms an advantageous device 13 for improving the electromagnetic compatibility in particular of the control unit 2. For this purpose, the spring element 8 is advantageously embodied in such a manner that it renders possible for electromagnetic pulses to be advantageously discharged even in the case of a high-frequency application. For this purpose, the spring element 8 is advantageously embodied as described below.

FIGS. 2A to 2D illustrate in this regard multiple views of a first exemplary embodiment of the spring element 8. In accordance with this exemplary embodiment, the spring element 8 is formed by two helical springs 14, 15 that are arranged in a coaxial manner with respect to one another. In this case, the helical springs 14, 15 are wound in opposite directions. FIG. 2B illustrates in this case in a single view the inner-lying helical spring 15 and FIG. 2C illustrates the outer-lying helical spring 14. The helical springs are connected to one another at their winding ends for example by means of a weld site 16 in a material-bonded, electrical and mechanical manner. As a consequence, the equivalent electrical circuit diagram illustrated in FIG. 2D is produced. The two helical springs represent in each case inductance L1, L2 that are however oriented in opposite directions. The electrical reactance of the respective helical spring 14, 15 increases to X_{L}=2_{Π} f L as the pulse frequency increases. As a consequence, the extent to which the electromagnetic pulses are discharged reduces as the pulse frequency increases and an increased number of interference signals are unintentionally output via the metal components. By virtue of the fact that two helical springs 14, 15 are provided, the winding sections 17, 18 of which are embodied or wound in opposite directions, the reactance reduces without additional electronic components being required for this purpose because the induced currents flow in opposite directions. A current pulse induces in the windings in each case a voltage that in the advantageous embodiment of the device 13 is oriented in the opposite direction with the result that the resulting voltage is less than the individual voltage and also consequently the resulting impedance. In the theoretical ideal case of identical coils, the induction voltages of the inductances L1 and L2 increase in a reciprocal manner. Optionally more than two helical springs 14, 15 are arranged in a coaxial manner with respect to one another in order to increase the number of inductances that are oriented in opposite directions and as a consequence to improve the power of the device 13. A side effect of the automated production process is that the spring of the device 13 is less inclined or not inclined at all to become disoriented or hooked in. The coaxial arrangement of the helical springs 14, 15 necessitates different winding diameters, as a result of which different spaces through which a magnet field flows are produced with the result that the coils comprise different inductances. A resulting apparent resistance is therefore still present but it is less than that of an individual helical spring 14, 15.

In accordance with an alternative exemplary embodiment, as illustrated in FIGS. 3A and 3B, the winding sections 17, 18 that are oriented in different directions in a single helical spring 19 are realized. The winding sections 17, 18 are in this case embodied in an axial manner one behind another in the helical spring 19. This produces the equivalent circuit diagram illustrated in FIG. 3B in which the inductances L1 and L2 are connected in series.

In the case of the present exemplary embodiment, it is ensured as a result of the winding radii or winding diameters being identical that the inductances L1 and L2 are identical. However, it is not possible to provide full compensation as a result of the series connection.

It is preferred that at least one spring end of the spring element 8 is embodied so that it can be fixed on the printed circuit board 5 by means of a SMD soldering process. In accordance with a further exemplary embodiment (not illustrated here) the winding direction of the windings or winding sections advantageously changes more than only twice, with the result that the helical spring 19 comprises for example 3 winding sections that comprise different winding directions lying one behind the other.

1. A device for improving the electromagnetic compatibility of electrical/electronic units, comprising:
an electrically conductive spring element configured to be arranged pre-stressed between a first electrical/electronic unit and a second unit in order to produce an electrical connection between the two units, the spring element including at least one helical spring with at least two winding sections that are oriented in different directions.

2. The device as claimed in claim 1, wherein the winding sections are configured in a coaxial manner with respect to one another in two helical springs.

3. The device as claimed in claim 2, wherein the helical springs are configured as one piece with one another.

4. The device as claimed in claim 2, wherein the helical springs are configured separately and are connected to one another in an electrically conductive manner.

5. The device as claimed in claim 2, wherein the helical springs are connected to one another in a material-bonded manner at least at one spring wire end.

6. The device as claimed in claim 1, wherein the winding sections are configured in an axial manner one behind the other in a helical spring.

7. An electrical/electronic unit, comprising:
a printed circuit board that comprises multiple electrical/electronic components and tracks; and
at least one device configured to improve the electromagnetic compatibility of the electrical/electronic unit, the device comprising an electrically conductive spring element that is configured to be arranged pre-stressed between the printed circuit board and a second unit, in order to produce an electrical connection between the printed circuit board and the second unit,
wherein the spring element includes at least one helical spring with at least two winding sections that are oriented in different directions.

8. An assembly, comprising:
a first electrical/electronic unit;
a second unit; and
at least one device configured to improve the electromagnetic compatibility at least of the first unit, the device comprising an electrically conductive spring element that is held in a pre-stressed manner between the first unit and the second unit, the spring element including at least one helical spring with at least two winding sections that are oriented in different directions.

9. The assembly as claimed in claim 8, wherein the first unit comprises a printed circuit board that comprises multiple electrical/electronic components and tracks, and wherein the at least one helical spring lies in an axial manner at one end against an electrical connection contact of the printed circuit board and at the other end against an electrically conductive contact element of the second unit.

10. The assembly as claimed in claim 9, wherein the electrically conductive contact element of the second unit is an electrically conductive housing or housing part of the second unit.

11. The device as claimed in claim 1, wherein the first electrical/electronic unit is configured as a control unit and the second unit is configured as a brake system or an actuator.

12. The electrical/electronic unit as claimed in claim 7, wherein the electrical/electronic unit is configured as a control unit of a motor vehicle.

13. The assembly as claimed in claim 8, wherein the second unit is configured as one of a brake system, an actuator, an electric motor, an electric pump, a transmission, or a hydraulic block.
